(19) United States
(12) Patent Application Publication
(10) Pub. No.: US 2011/0209696 A1
(43) Pub. Date: Sep. 1, 2011

(54) THREE POINT SOLAR TRACKING SYSTEM AND METHOD

(76) Inventor: Gregory M. O'Rourke, San Francisco, CA (US)

(21) Appl. No.: 12/913,375

(22) Filed: Oct. 27, 2010

Related U.S. Application Data
(60) Provisional application No. 61/255,317, filed on Oct. 27, 2009.

(51) Int. Cl. F24J 2/38; H01L 31/052

(52) U.S. Cl. 126/600; 136/246

(57) ABSTRACT

A three point solar tracking system and method are provided.

### PRIORITY CLAIM/RELATED APPLICATION

This patent applications claims the benefit under 35 USC 119(e) and 35 USC 120 to U.S. Provisional Patent Application Ser. No. 61/255,317 filed on Oct. 27, 2009 and entitled “Three Point Solar Tracking System and Method”, the entirety of which is incorporated herein by reference.

### FIELD

The disclosure relates generally to a system for tracking the sun in a solar energy system.

### BACKGROUND

Solar tracking systems are well known and use different mechanisms and technologies to track the sun. Solar tracking systems move/rotate one or more solar panels during the course of the day to ensure that as much of the sun's energy is captured by the solar panels and turned into electricity. However, none of the existing solar tracking systems have a three point solar tracking system and method and it is to this end that the disclosure is directed.

### BRIEF DESCRIPTION OF THE DRAWINGS

FIGS. 1A-1C illustrate a top view of a first embodiment of a three point solar tracker in a first, second and third positions, respectively;

FIG. 2 illustrates a side view of the first embodiment of the three point solar tracker;

FIG. 3A-3E illustrate five positions of a solar module using the first embodiment of the three point solar tracker;

FIG. 4 illustrates a multiple solar module implementation of a second embodiment of the three point solar tracker without solar panels;

FIG. 5 illustrates the multiple solar module implementation of the second embodiment of the three point solar tracker with solar panels;

FIG. 6 illustrates a multiple installation multiple solar module implementation of the second embodiment of the three point solar tracker;

FIG. 7 illustrates more details of the control module of the second embodiment of the three point solar tracker;

FIG. 8 illustrates more details of the extension module of the second embodiment of the three point solar tracker;

FIGS. 9A and 9B are a perspective top view and end view, respectively of the control module;

FIG. 10 illustrates more details of the tracker control box that is part of the control module;

FIG. 11 illustrates more details of the coupling between the control unit and the solar panel of the second embodiment of the three point solar tracker;

FIGS. 12A and 12B illustrate the control module being used to adjust the altitude of the solar panels in a first direction;

FIGS. 13A and 13B illustrate the control module being used to adjust the altitude of the solar panels in a second direction;

FIGS. 14A and 14B illustrate the control module being used to adjust the azimuth of the solar panel in a first direction; and

FIGS. 15A and 15B illustrate the control module being used to adjust the azimuth of the solar panel in a second direction.

### DETAILED DESCRIPTION OF ONE OR MORE EMBODIMENTS

The disclosure is particularly applicable to a solar tracker system as shown in the figures and described below and it is in this context that the disclosure will be described. It will be appreciated, however, that the system and method has greater utility.

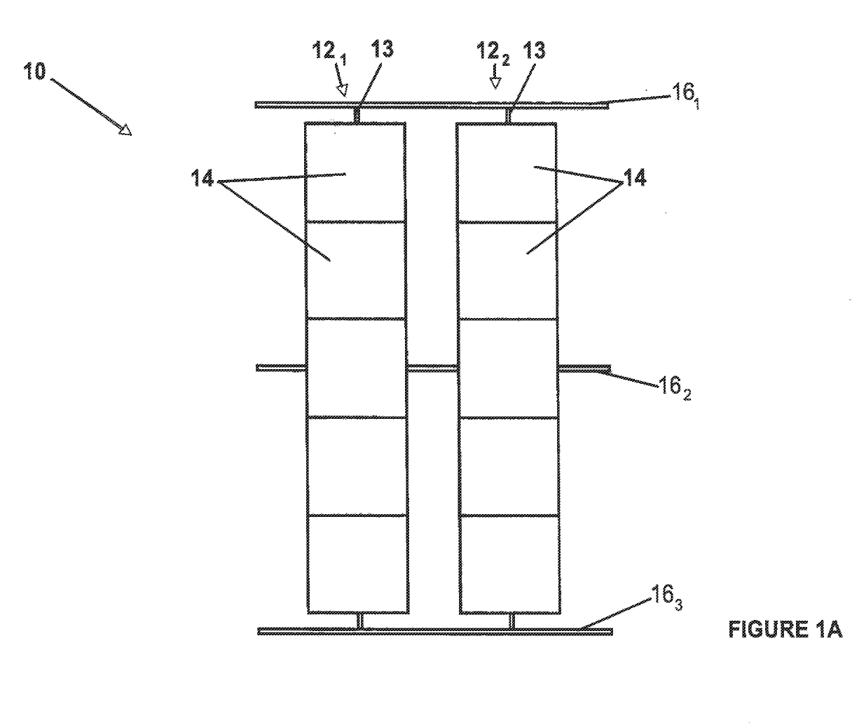

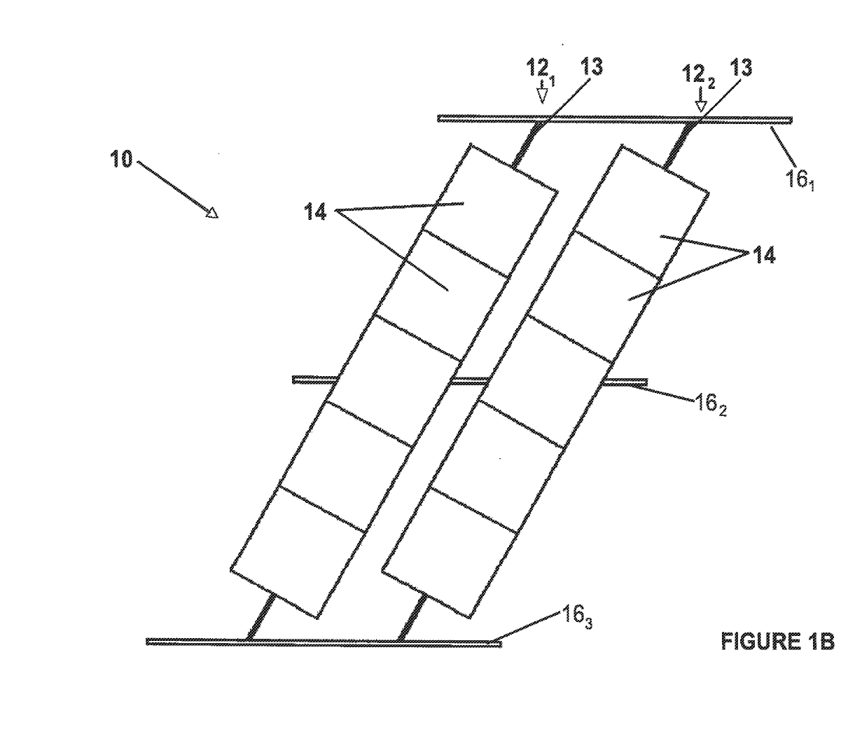

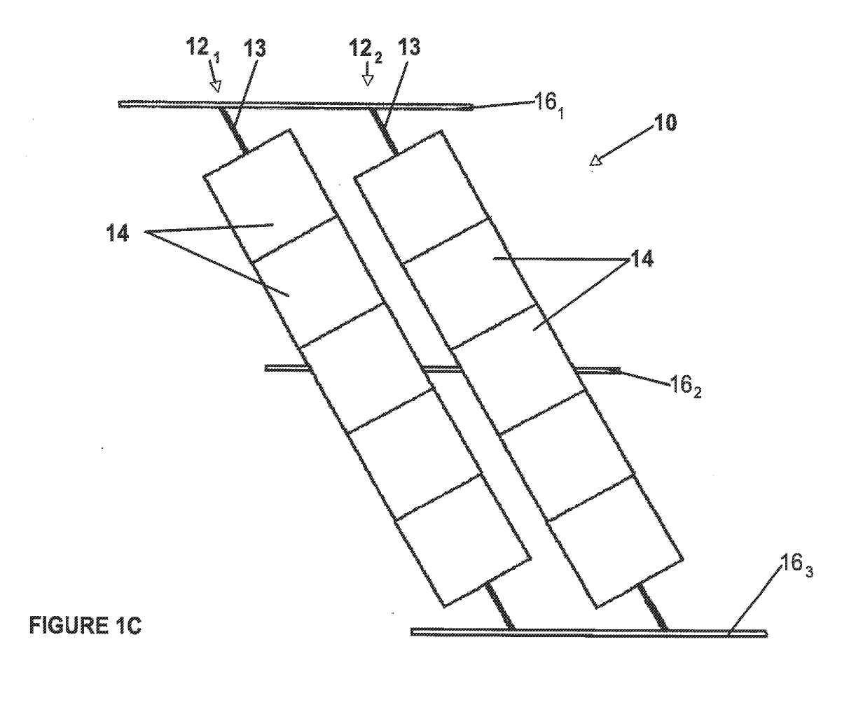

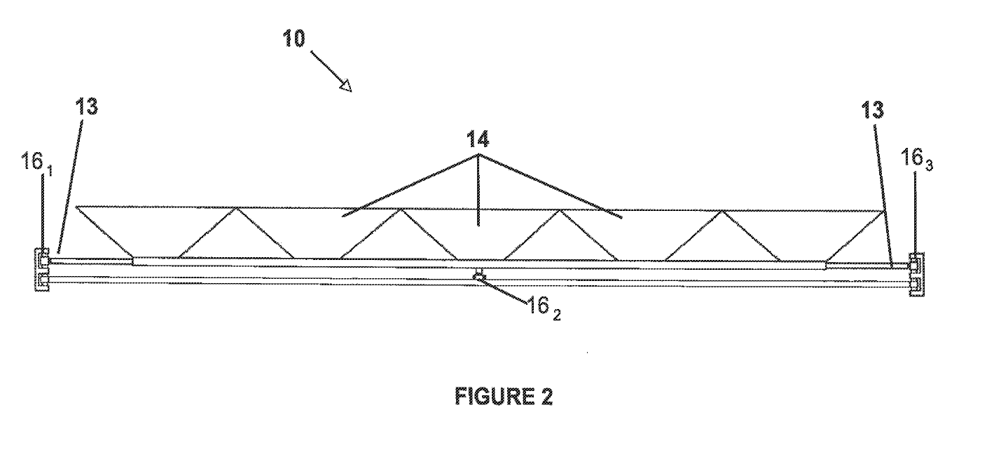

FIGS. 1A-1C illustrate a top view of a first embodiment of a three point solar tracker 10 in a first, second and third positions, respectively and FIG. 2 illustrates a side view of the three point solar tracker 10. The solar tracker 10 has a first row 12₁ of one or more solar modules 14 (five in this example) and a second row 12₂ of one or more solar modules 14 (five in this example) wherein the first and second rows may be substantially parallel as shown in one embodiment. However, the first and second rows may have other orientations with respect to each other, there may be additional/fewer rows of solar modules than shown in FIGS. 1A-1C and the first and second rows may have a different number of solar modules than shown in FIGS. 1A-1C. Each row 12₁, 12₂ may be mounted on a rail 13 that may be attached to the center of each solar module 14 as shown. In addition, the solar tracker 10 has a first rail 16₁, a second rail 16₂ and a third rail 16₃ that are mounted across the rows 12₁, 12₂ of solar modules. Each of the first rail 16₁, the second rail 16₂ and the third rail 16₃ may be mounted to the either the rails 12 or the solar modules 14 by one or more pivot points (not shown in FIGS. 1A-1C.) The pivot points of the first and third rails 16₁, 16₃ (also known as the outer rails) may operate a single axis of rotation to control azimuth of the solar modules. In the embodiment shown, the first and third rails 16₁, 16₃ are parallel to each other and always at the constant distance from one another as shown in FIGS. 1A-1C. In one embodiment, to maintain the distance between the outer rails, the pivot connection may use extending rods. For example, the rail 13 may be able to extend when in the position shown in FIGS. 1B or 1C as compared to the position shown in FIG. 1A. The expansion provides multiple modules linearly connected to use the same solar sensor and reduces the number of actuators and motors required for tracking

The second rail 16₂ (which may also be known as the center rail) may have a center pivot point that can be operated by connecting with the outer rails and that operates a single axis of rotation to control altitude. The rails 16₁, 16₂, 16₃ may be linear slide rails operated by linear actuators (not shown) connected to a tracking sensor (not shown.) The tracking sensor sends signals to the actuators or motor controls to adjust positions. The actuators move the outer rails linearly in opposite directions while maintaining parallelism which causes the module to rotate and changes the azimuth coordinate of the module face. The actuator for the center pivot point receives signals from the sensor for linear adjustments which causes the module to vertically rotate which changes the altitude of the module face.

The tracking sensor and the module may be calibrated to direct center south facing at 54 deg. The tracking sensor may also be replaced by computerized tracking such as those used in telescopes. The sensor or computerized tracking may be connected to GPS for accuracy. A computerized tracking system may utilize solar declination algorithms for more accuracy.

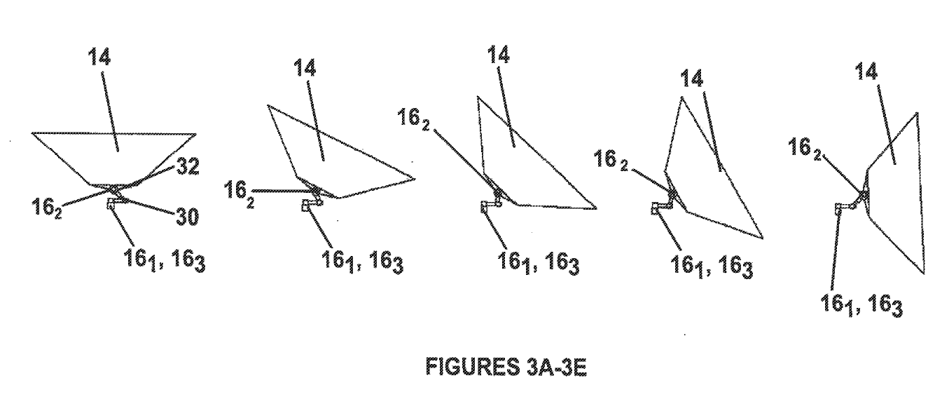

FIG. 3A-3E illustrate five positions of a solar module 14 of the three point solar tracker for the altitude coordinate. In particular, the outer rails 16₁, 16₃ are shown as well as the center rail 16₂. Each solar module may also have a neck piece 30 and a slide rod 32 as shown. Each figure represents a side view that shows how that axis rotates using the neck piece 30 fixed at a specific angle with the slide rod 32 that would be moved linearly forward and back to do the rotation. There is also a short extending rod in the neck to hold it together when the distance changes between the slide rod and the neck. A bearing in the neck allows for the altitude rotation and the azimuth rotation to operate simultaneously. In operation, the horizontal rotation of the solar module is controlled by the outer rails 16₁, 16₃ and the vertical rotation is controlled by the center rail 16₂ which is connected with the slide rod to the neck.

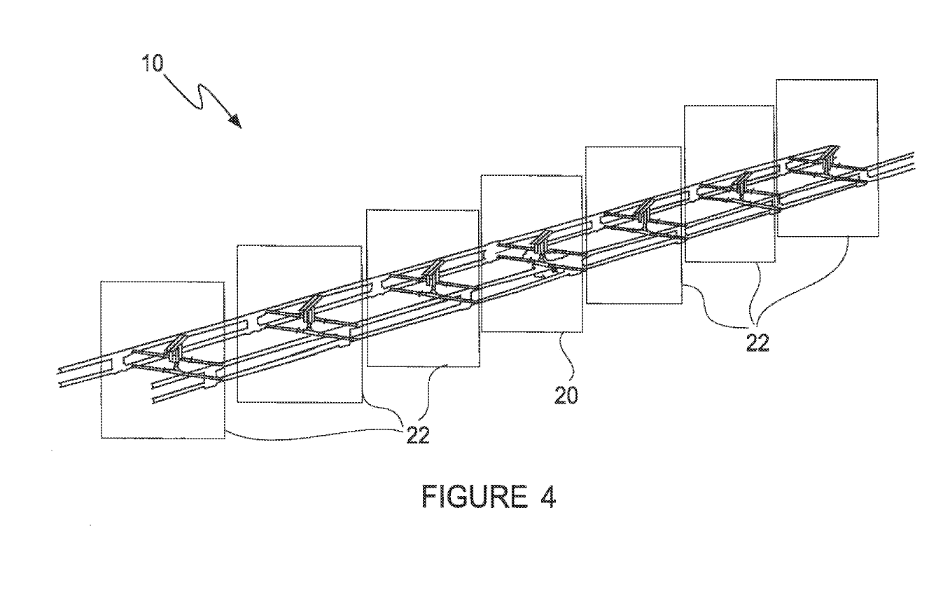

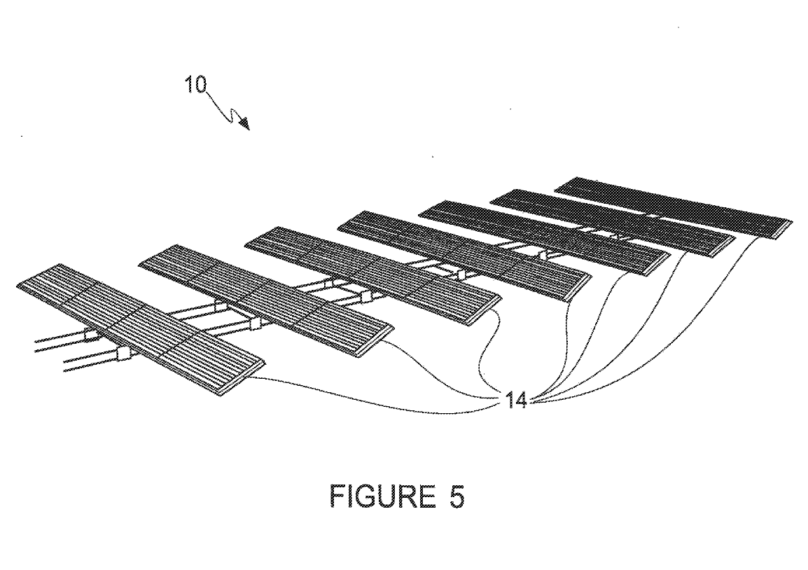

FIG. 4 illustrates a multiple solar module implementation of a second embodiment of the three point solar tracker 10 without solar panels and FIG. 5 illustrates the multiple solar module implementation of the second embodiment of the three point solar tracker 10 with solar panels/modules 14 wherein the three point solar tracker moves all of the solar modules 14 simultaneously to track the movement of the sun across the sky during daylight hours. As shown in FIG. 4, the second embodiment of the three point solar tracker 10 may include a control module 20. The second embodiment of the three point solar tracker 10 may, in certain implementations, also include one or more extension modules 22. For example, in the seven solar module implementation shown in FIGS. 4-5, the three point solar tracker 10 has six extension modules 22 and one control module 20. In an implementation with a single solar module, no extension module would be required. In implementations that have the control module 20 and the extension modules 22, the control module 20 may be located between the extension modules as shown in FIGS. 4-5, but may also be located at other positions and the disclosure is not limited to any particular orientation of the control module with respect to the extension modules. In the system, there is one control tracker module 20 with a single set of control hardware, which includes the controller itself, and the actuators. In the system, a single control module 20 can operate with up to 50 extension modules connected end to end. In operation, the three point solar tracker moves the one or more solar modules to track the motion of the sun in the sky.

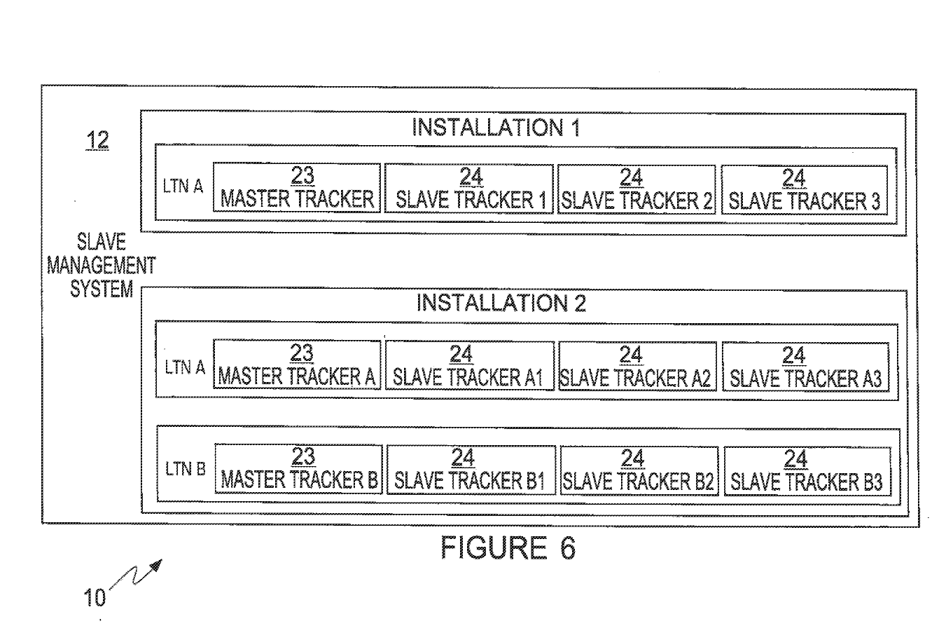

FIG. 6 illustrates a multiple installation multiple solar module implementation of the second embodiment of the three point solar tracker. In particular, the solar tracker 10 may be implemented using a global solar management system 12 that operates/manages one or more installations of solar modules. In each installation, for management purposes, there may be at least one master tracker node 23 and one or more slave tracker nodes 24 wherein the slave tracker nodes replicate the functionality of the master tracker node for failover capability. In this example, the overall operation and tracking of the sun by the various installations may be managed by the global management system 12. Now, more details of the control module is described.

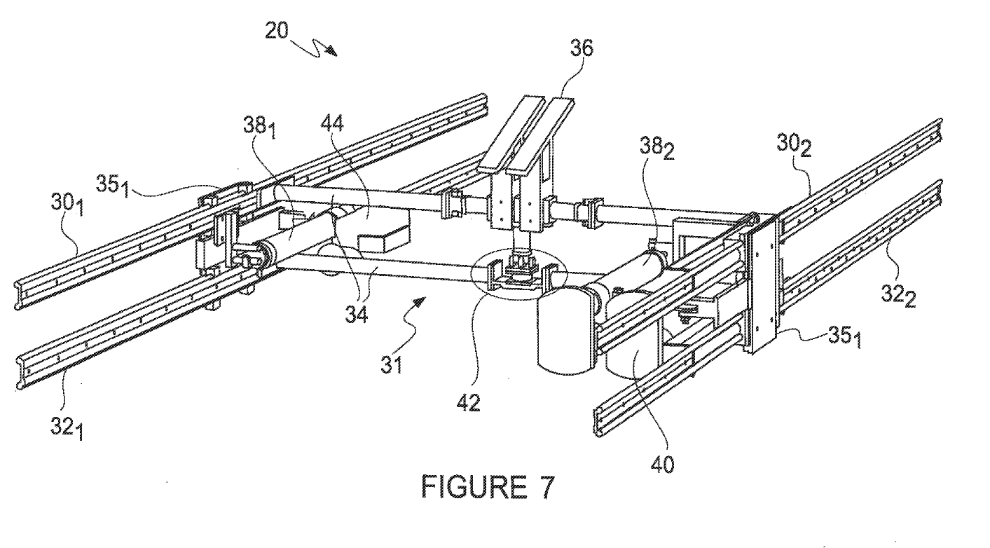

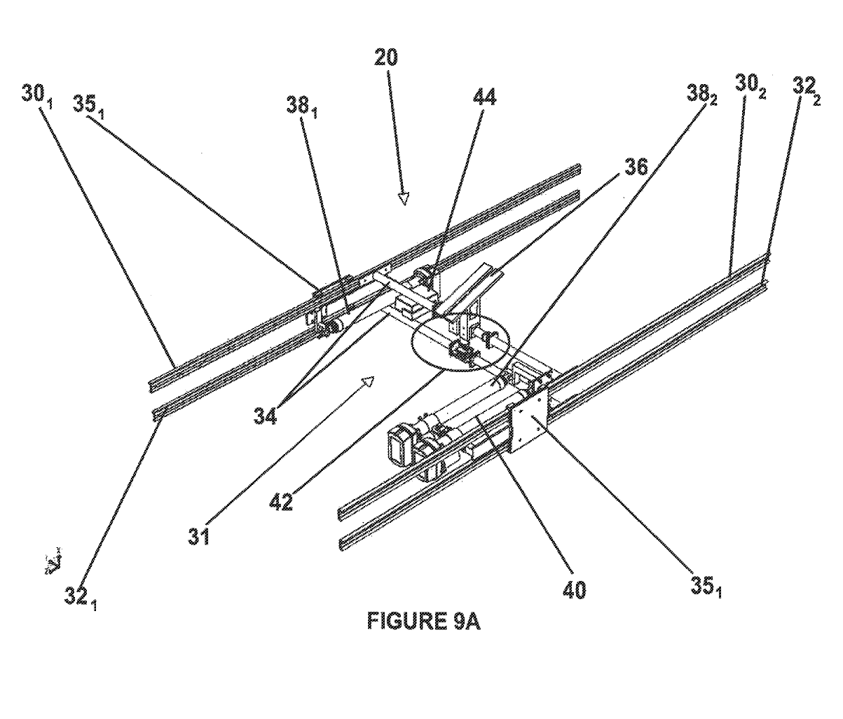

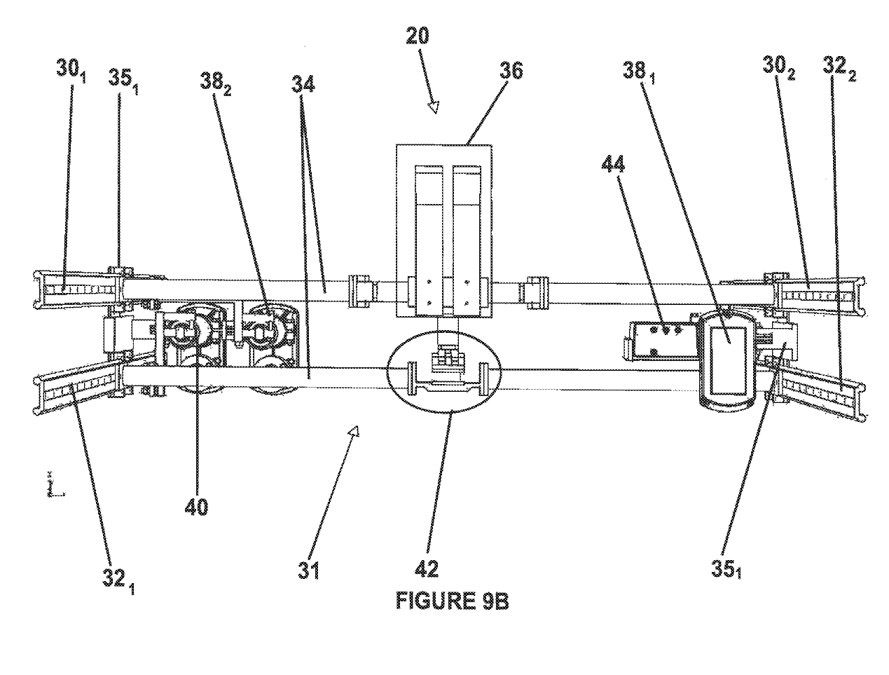

FIG. 7 illustrates more details of the control module 20 of the second embodiment of the three point solar tracker and FIGS. 9A and 9B are a perspective top view and end view, respectively of the control module 20. The control module has a first and second azimuth rail 30₁, 30₂, that may be horizontally spaced apart from each other and a first and second altitude rail 32₁, 32₂, that may also be horizontally spaced apart from each other. In one implementation that is shown in FIG. 7, the pair of azimuth rails and the pair of altitude rails are vertically above each other, but can also be in other configurations. As described below in more detail, the first and second azimuth rail 30₁, 30₂ are used to control the azimuth of each solar panel/module that is attached to a solar panel/module mount 36 and the first and second altitude rail 32₁, 32₂ are used to control the altitude of the each solar panel/module that is attached to a solar panel/module mount 36. Each set of rails is spaced horizontally between a control portion 31 of the control module 20.

The control portion 31 of the control module further comprises a first and second control members 34 that connect the rails to the control portion 31 as well as to the solar panel/module mount 36 and first and second frame members 35₁, 35₂ that connect the control members 34 and actuators and allows the rails to slide. The control portion further comprises the solar panel/module mount 36 that is coupled to the control members 34 to move the solar panel/module that is attached to the mount. The control portion 31 further comprises a first azimuth actuator 38₁ and a second azimuth actuator 38₂ that, in response to control signals, moves one or both of the azimuth rails 30₁, 30₂ as described below in more detail and an altitude actuator 40 that, in response to control signals, move one or both of the altitude rails 32₁, 32₂ as described below in more detail. The lower control member 34 is coupled to the solar panel/module mount 36 by a swivel 42 that transfers the motion of the altitude rails 32₁, 32₂ into motion of the solar panel/module. The control portion 31 also has a tracking control box 44 that controls the actuators 38₁, 38₂, 40 and thus controls the positioning of the solar panel/module so that it tracks the sun.

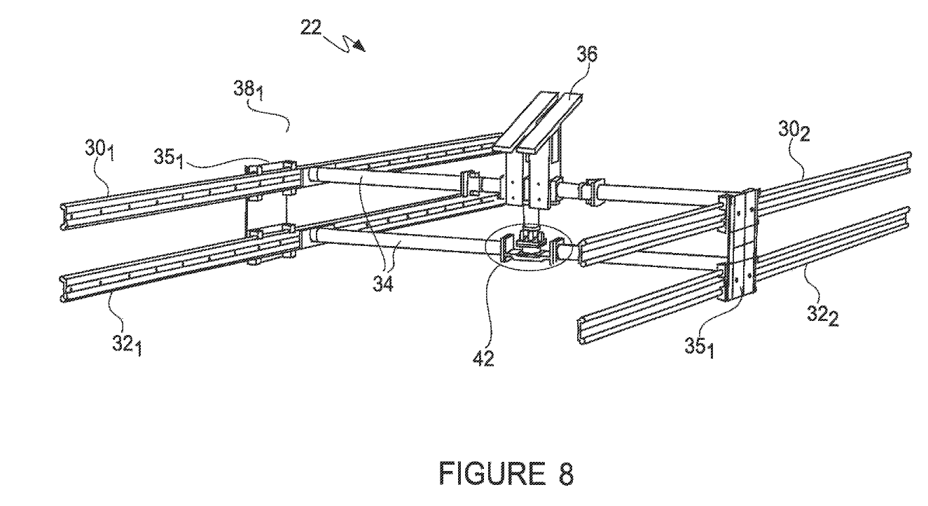

FIG. 8 illustrates more details of the extension module 22 of the second embodiment of the three point solar tracker. The extension module 22 has some of the same elements as the control module (designated with the same reference numeral) that operate in the same manner as with the control module so that they are not described further. The extension module 22 does not have the control portion 31 or the actuators so the extension module 22 acts as a slave to the control module 20 and moves the solar panel/module in synchronization with the movements of the solar panel/module that is being controlled by the control portion 31.

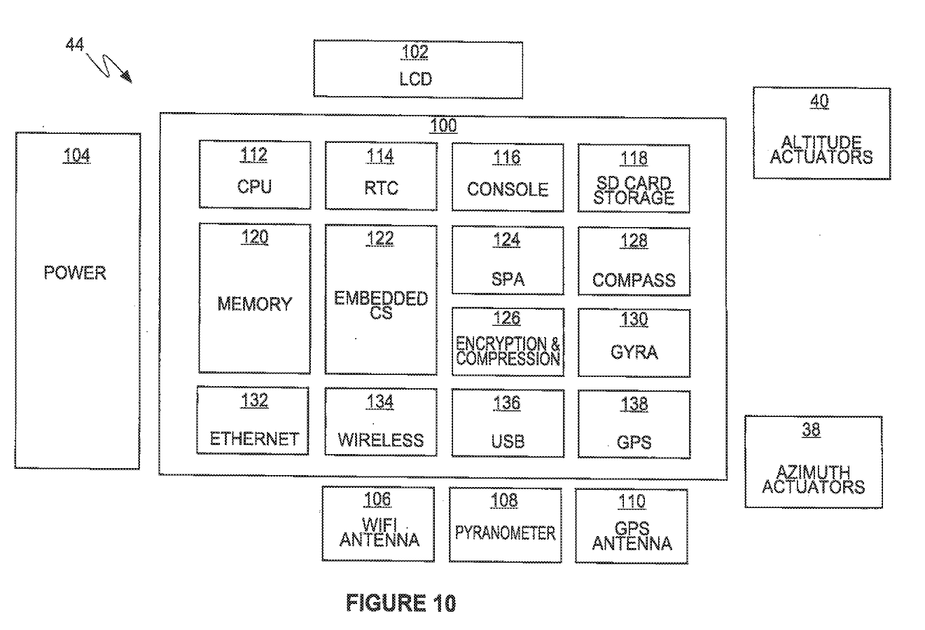

FIG. 10 illustrates more details of the tracker control box 44 that is part of the control module. The tracker control box 44 may have a chassis 100 (that may be waterproof and weatherproof), a display 102 (such as a LCD), a power source 104, such as a battery, rechargeable battery, solar powered, etc., a Wifi antenna 106, a pyranometer 108 and a GPS antenna 110 that are connected to/associated with the chassis 100 in addition to the actuators 38, 40 described above. The chassis 100 may house, for example, one or more processing units 112, real time clock unit 114, a console 116, an SD card storage area 118, an amount of memory 120, an embedded operating system (OS) 122, a solar position algorithm (SPA) 124 with a 0.005° of tolerance that may be programmed into its own ASIC, an encryption and compression module 126, a compass 128, a gyroscope 130, an Ethernet connection 132, a wireless circuit 134, a USB port and circuitry 136 and GPS circuitry 138.

In operation, the tracking control box may have a controller/processing unit that executes a plurality of line of code (microcode or the like) to control the operation and functioning of the three point solar tracker system and implement a three point solar tracking method. The controller may perform system startup and check for working devices, gps, compass, gyroscope, rtc (real time clock) and the pyranometer that are part of the tracking control box or located elsewhere. The controller may also check for working actuator by, for example. sending/receiving signal feedbacks from each actuator. The controller may also read data: compass (dir S), gps (lat,long,time), gyroscope (xyz) information from those components that are part of the tracker control box or located elsewhere. The controller may also determine planar tilt using gyroscope (xyz) (0.05 deg tolerance), determine directionality using the compass to determine exact South (0.01 deg tolerance) and generate compensation x-y-z distance metric for ‘zero’ value. The controller, if either [x-y-z] metric is greater than 5 deg from x,y,z center, may send an alert for manual adjustments of the solar tracker. The controller, as part of the start up process may also determine location coordinates using GPS data, determine time value using GPS data and calibrate the system to zero position by sending signal to actuator controller [zero,x,y,z].

Each actuator described above has a controller that uses a process to generate 2-axis mechanical movements. The azimuth actuator 38₁ is mounted in an opposite direction as the azimuth actuator 38₂ and altitude actuator 40. The azimuth actuator 38₁ is used to operate Arm A1 connected to the actuator and rail 30₁ in bi-directional horizontal movement. The azimuth actuator 38₂ is used to operate Arm A2 connected to the actuator and rail 30₂ in bi-directional horizontal movement. The altitude actuator 40 is used to operate Arm B1/B2 connected to the actuator and rails 32₁, 32₂ in bi-directional horizontal movement. When any of the actuators move due to [+] or [−] control signals, the actuator extends or retracts its piston and the piston is directly connected to the corresponding rail with a pin-mount. When the piston moves the rail and directly connected arm is horizontally moved in the same direction and each arm is a telescoping tube that allows the change in length required as the T mount 36 is rotated. The arms are connected to the T mount using vertical hinges. At the zero point (neutral), the pistons are exactly 50% extended from the actuators 38₁, 38₂. For azimuth rotation (axis 1), the T mount 36 in the center of the tracker is rotated. The system has a default 82° safety limit-stop to prevent over-rotation of the T mount and the safety stops the system after rotating 82° East or West from the zero point. The safety stops allow for a total azimuth range of 164° East to West tracking rotation (axis 1).

At the zero point, the pistons are exactly 75% extended from the actuator 40. The T mount 36 stands vertically on a horizontal 360° swivel base 42 connected with a hinge. The swivel base 42 is connected directly between Arms B1 and B2 which are the bottom connecting members 34. The telescoping action from altitude Arms B1 and B2 allows the T mount base post to position at an angle. For altitude or tilt adjustment (axis 2), the T mount is tilted forward and backward from its base. The system has a default N60° and S20° safety limit-stop to prevent over-tiling of the T mount. The N60° safety stops the system after tilting 60° backward from the zero point and the S20° safety stops the system after tilting 20° forward from the zero point which allows for a total altitude range of 80° north to South tracking rotation (axis 2). During altitude adjustment arm B1 will extend when B2 retracts and B1 will retract when B2 extends.

When first started, the solar tracking system is calibrated to the zero point (azimuth 180°, altitude22°). The SPA (solar position algorithm) determines the current solar position (azimuth,altitude) using GPS. The system then enters tracking mode and sends position [spa,azi,alt] information to the actuator controller. Each actuator controller converts the position [azi,alt] to [x,y,z] coordinates and all actuators are sent appropriate signals [+/−] to adjust the positions. An auto-horizon feature utilizes the pyranometer to read solar irradiation data and the pyranometer provides constant irradiation readings, recorded once per second and the irradiation data is mapped against solar position to calculate the horizon azimuth and altitude. During operation, the actuator controller is sent dawn/dusk values [pyrano,dw,ds] and these values are used to optimize start/stop times for daily tracker usage.

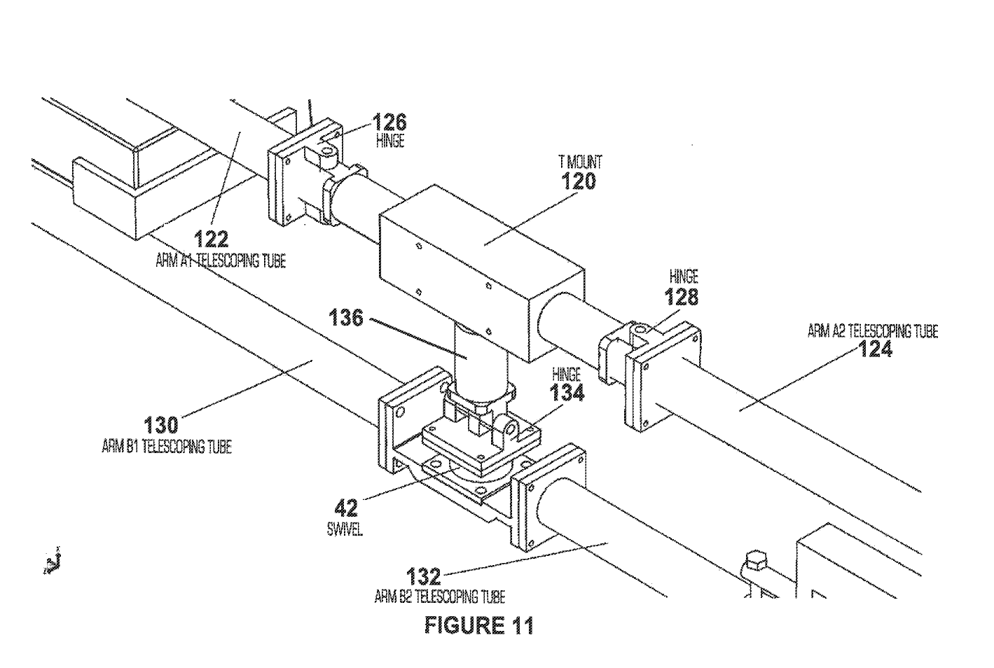

FIG. 11 illustrates more details of the coupling between the control unit and the solar panel of the second embodiment of the three point solar tracker. As shown, the swivel 42 is coupled by a hinge 134 to a telescoping tube 136 that is then connected to a T mount 120. The mount 36 described above rests on/fits over the T mount 120. The swivel is also coupled to a first altitude arm 130 (which may be a telescoping tube) and a second altitude arm 132 (which may be a telescoping tube) which are then connected to the altitude rails 32₁, 32₂ as described above so that the movement of the altitude rails moves the arms which in turn causes movement of the swivel and hinge to change the tilt of the solar panel/module. The T mount 120 is connected, by hinges 126, 128 to a first azimuth arm 122 and a second azimuth arm 124 (that may each be a telescoping tube) and the arms 122, 124 are connected to the azimuth rails 30₁, 30₂ as described above so that the movement of the azimuth rails moves the arms which in turn causes movement of the T mount 120 to change the azimuth angle of the solar panel/module.

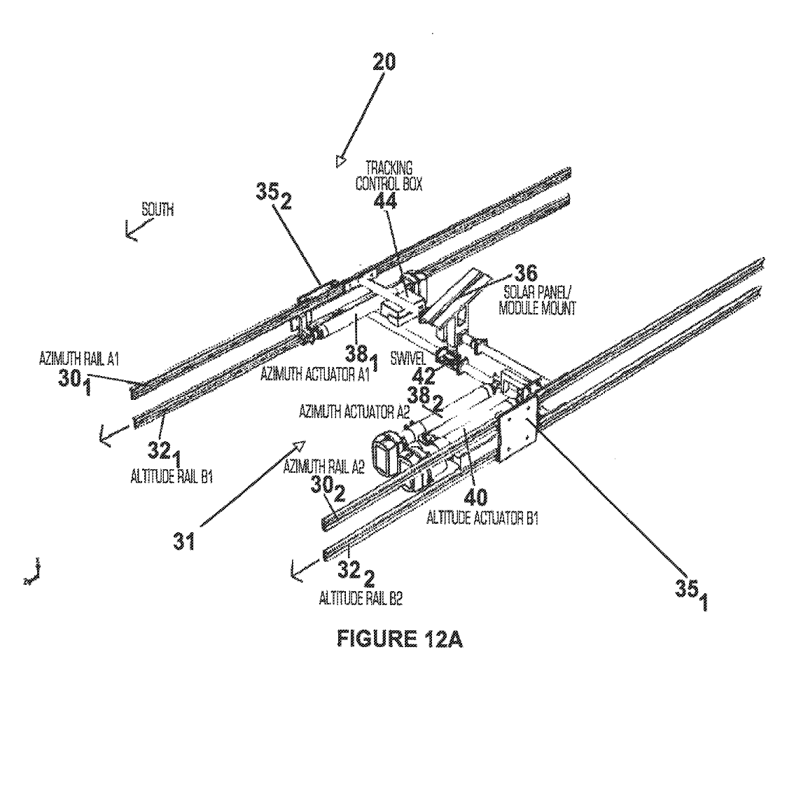

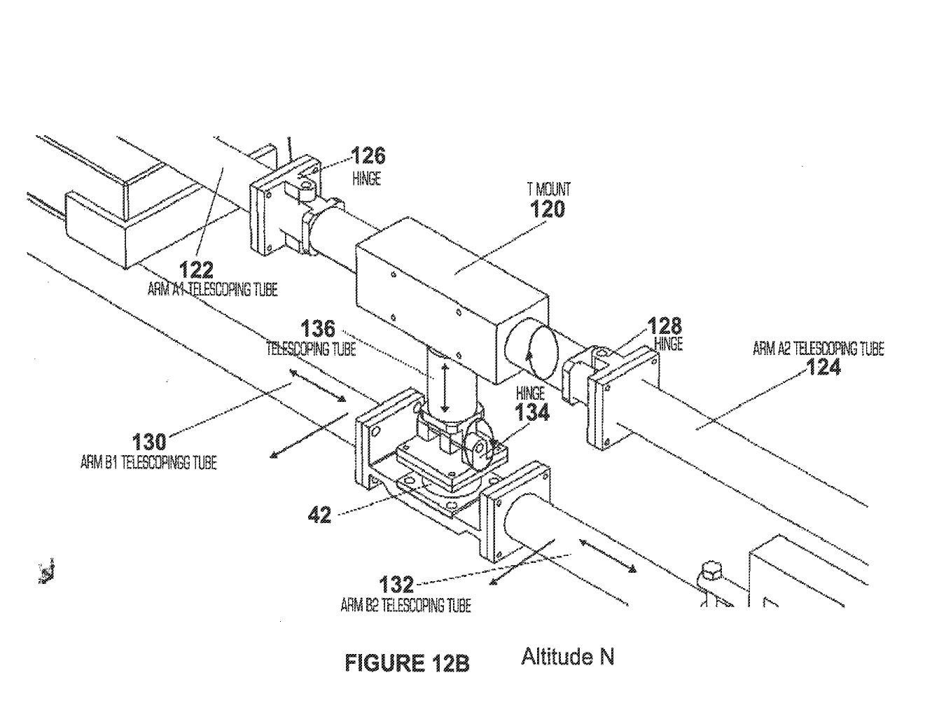

FIGS. 12A and 12B illustrate the control module being used to adjust the altitude of the solar panels in a first direction (North). In particular, to generate North directional tilt movement from zero to N60° limit (backward tilt), the following processes are performed:
1. Actuator B1 40 is given [−] signal;
2. Actuator retracts its piston to correspond to the control signal;
3. Rails B1 (32₁) and B2 (32₂) move in the same direction;
4. Rails move Arms B1 and B2 in the same direction (towards the front as shown in FIG. 12B);
5. Arms A1 and A2 telescoping tubes extend or retract depending on azimuth position; and
6. The above actions generate backward tilt of the T mount.

To generate North directional tilt movement from S20° limit to zero (backward tilt)
1. Actuator B1 40 is given [−] signal;
2. Actuator retracts its piston to correspond to the control signal;
3. Rail B1 (32₁) and B2 (32₂) move in the same direction;
4. Rails move Arms B1 and B2 in the same direction (towards the front as shown in FIG. 12B);
5. Arms A1 and A2 telescoping tubes extend or retract depending on azimuth position; and
6. The above actions generate backward tilt of the T mount.

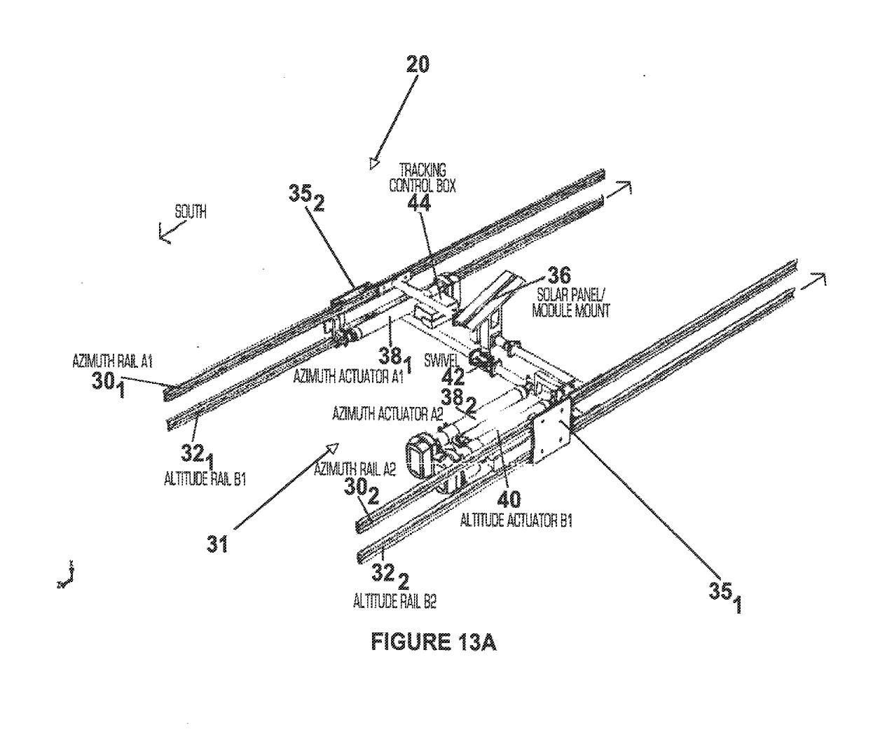

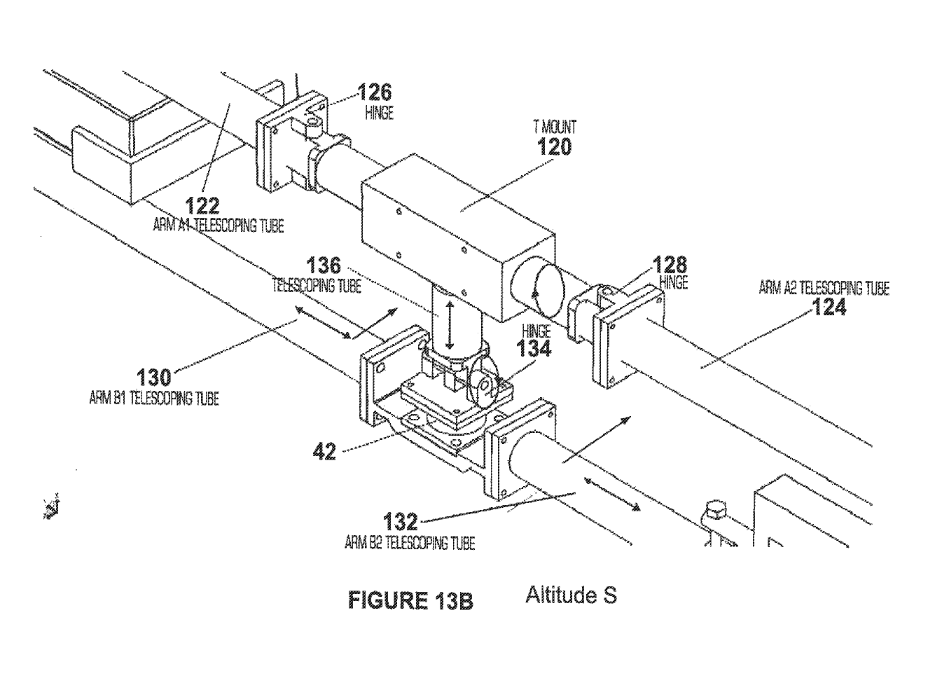

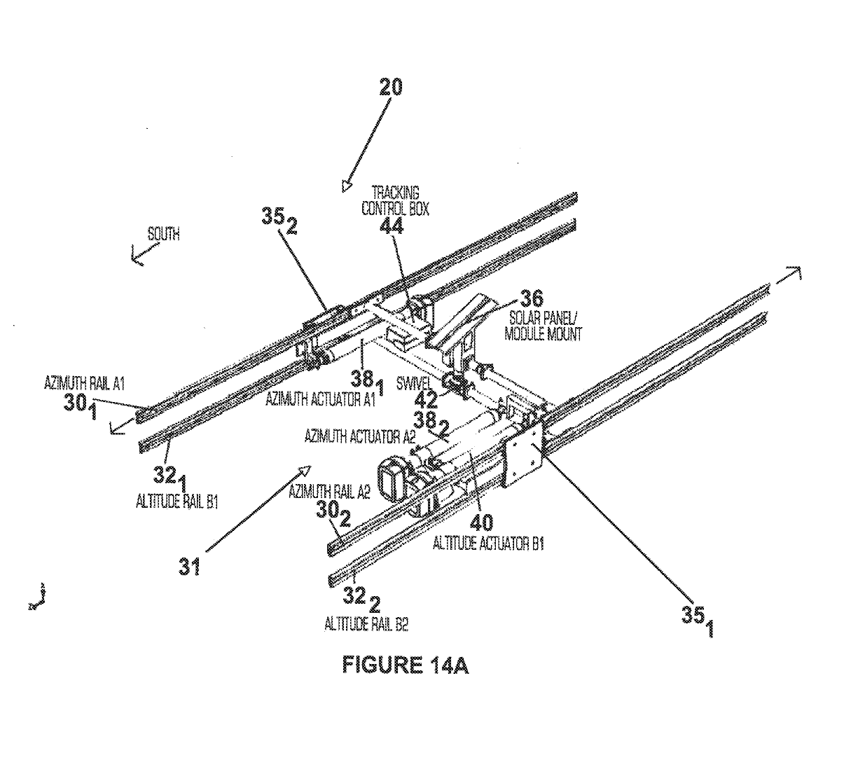

FIGS. 13A and 13B illustrate the control module being used to adjust the altitude of the solar panels in a second direction in which the solar panel/module is tilted forwards.

To generate North directional tilt movement from zero to S20° limit (forward tilt), the following processes are performed:
1. Actuator B1 40 is given [+] signal;
2. Actuator extends its piston to correspond to the control signal;
3. Rail B1 (32₁) and B2 (32₂) move in the same direction;
4. Rails move Arms B1 and B2 in the same direction;
5. Arms A1 and A2 telescoping tubes extend or retract depending on azimuth position; and
6. The above actions generate forward tilt of the T mount.

To generate North directional tilt movement from N60° limit to zero (forward tilt), the following processes are performed:
1. Actuator B1 40 is given [+] signal;
2. Actuator extends its piston to correspond to the control signal;
3. Rail B1 (32₁) and B2 (32₂) move in the same direction;
4. Rails move Arms B1 and B2 in the same direction;
5. Arms A1 and A2 telescoping tubes extend or retract depending on azimuth position; and
6. The above actions generate forward tilt of the T mount.

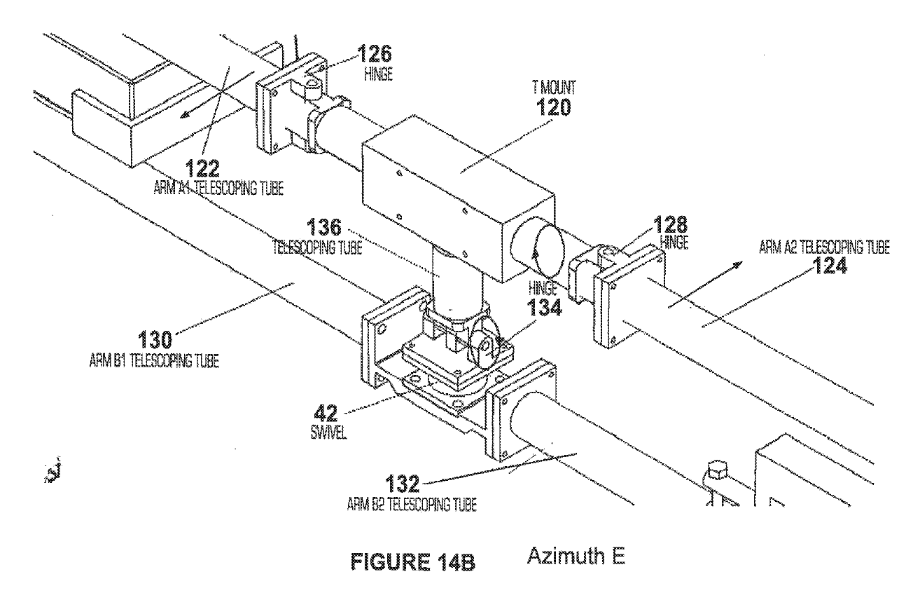

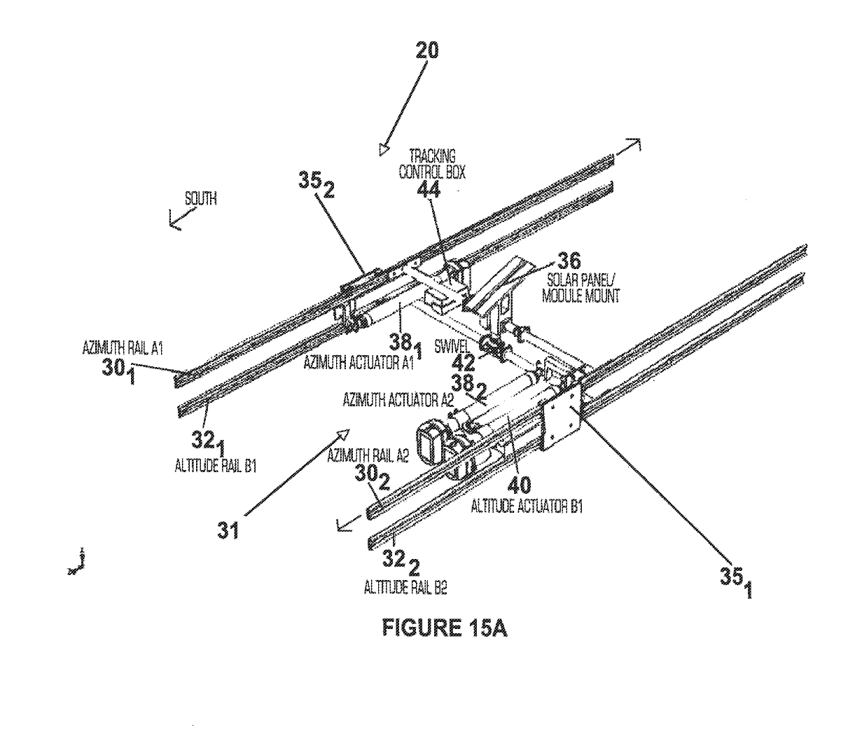

FIGS. 14A and 14B illustrate the control module being used to adjust the azimuth of the solar panel in a first counterclockwise direction. In particular, to generate East directional rotational movement from zero to 82° limit (counterclockwise), the following processes are performed:
1. Actuator A1 (38₁) is given [+] signal and Actuator 38₂ is given [+] signal;
2. Actuators extend pistons to correspond to the control signals;
3. Rail A1 (30₁) and Rail A2 (30₂) move in opposite directions;
4. Rails move Arms A1 and A2 in opposite directions;
5. Arms A1 and A2 telescoping tubes extend toward the T mount as they move; and
6. The above actions generates a counterclockwise rotation of the T mount.

To generate East directional rotational movement from 82° limit to zero (counterclockwise), the following processes are performed:
1. Actuator A1 (38₁) is given [+] signal and actuator 38₂ is given [+] signal;
2. Actuators extend pistons to correspond to the control signals;
3. Rail A1 (30₁) and Rail A2 (30₂) move in opposite directions;
4. Rails move Arms A1 and A2 in opposite directions;
5. Arms A1 and A2 telescoping tubes retract away from the T mount as they move; and
6. The above actions generate a counterclockwise rotation of the T mount

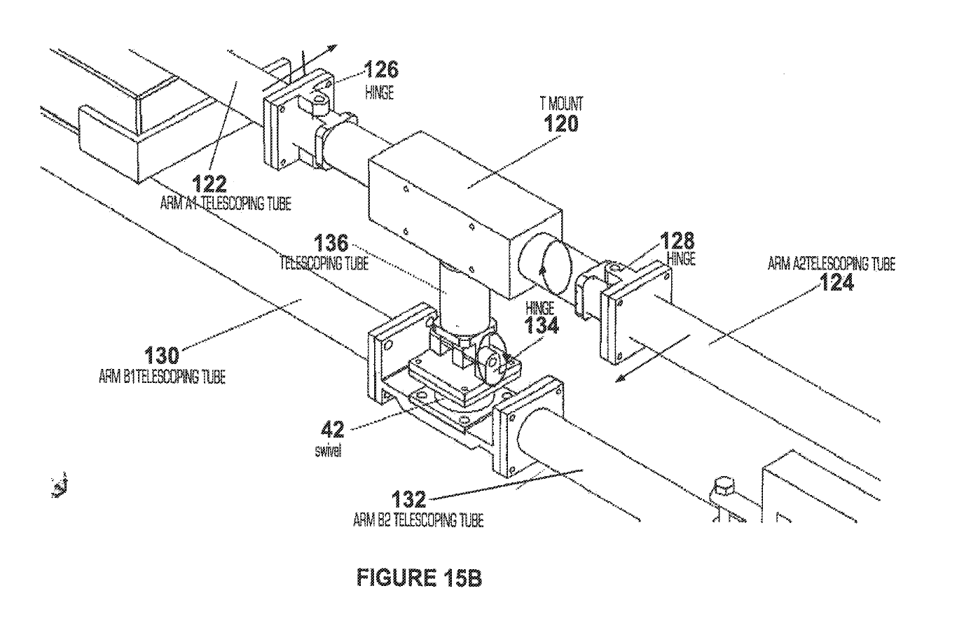

FIGS. 15A and 15B illustrate the control module being used to adjust the azimuth of the solar panel in a second clockwise. In particular, to generate West directional rotational movement from zero to 82° limit (clockwise), the following processes are performed:
1. Actuator A1 (38₁) is given [−] signal and actuator 38₂ is given [−] signal;
2. Actuators retract pistons to correspond to the control signals;
3. Rail A1 (30₁) and Rail A2 (30₂) move in opposite directions;
4. Rails move Arms A1 and A2 in opposite directions;
5. Arms A1 and A2 telescoping tubes extend toward the T mount as they move; and
6. The above actions generate a clockwise rotation of the T mount.

To generate West directional rotational movement from 82° limit to zero (clockwise), the following processes are performed:
1. Actuator A1 (38₁) is given [−] signal & actuator 38₂ is given [−] signal;
2. Actuators retract pistons to correspond to the control signals;
3. Rail A1 (30₁) and Rail A2 (30₂) move in opposite directions;
4. Rails move Arms A1 and A2 in opposite directions;
5. Arms A1 and A2 telescoping tubes extend toward the T mount as they move; and
6. The actions generate a clockwise rotation of the T mount.

While the foregoing has been with reference to a particular embodiment of the disclosure, it will be appreciated by those skilled in the art that changes in this embodiment may be made without departing from the principles and spirit of the disclosure, the scope of which is defined by the appended claims.

1. A solar tracker, comprising:
a first set of one or more solar modules mounted on a first rail;
a second set of one or more solar modules mounted on a second rail;
the first and second rails pivotably connected to a first outer rail at a first end of the first and second rails and pivotably connected to a second outer rail at a second end of the first and second rails opposite of the first end wherein the first and second outer rails control the azimuth of the solar modules; and
a center rail pivotably connected to the center of each of the set of one or more solar modules and being substantially perpendicular to the rail and second rails wherein the center rail controls the altitude of the solar modules.

2. A solar tracker, comprising:
a first azimuth rail and a second azimuth rail spaced apart for each other;
a first altitude rail and a second altitude rail spaced apart for each other;
an azimuth controller coupled to the first azimuth rail and the second azimuth rail that control the azimuth angle of a mount by moving the first azimuth rail and the second azimuth rail;
a tilt controller coupled to the first altitude rail and the second altitude rail that control the tilt angle of the mount by moving the first altitude rail and the second altitude rail; and
a controller that controls the azimuth controller and the tilt controller.

3. The solar tracker of claim 2 further comprising a set of arms that couple the first azimuth rail and the second azimuth rail to the azimuth controller.

4. The solar tracker of claim 3, wherein the azimuth controller further comprises a first azimuth actuator and a second azimuth actuator that control the movement of the first azimuth rail and the second azimuth rail.

5. The solar tracker of claim 2 further comprising a set of arms that couple the first altitude rail and the second altitude rail to the tilt controller.

6. The solar tracker of claim 5 further comprises a swivel mount that converts the movement of the first altitude rail and the second altitude rail into a tilting movement of the solar module.

7. The solar tracker of claim 2, wherein the tilt controller further comprises an altitude actuator that controls the movement of the first altitude rail and the second altitude rail.

8. The solar tracker of claim 2, wherein the controller automatically calibrates the azimuth controller and the tilt controller during start-up.

9. The solar tracker of claim 2, wherein the controller automatically determines a horizon during start-up.

10. A method for moving a solar module to track the sun, the method comprising:
providing a solar tracker that has a first azimuth rail and a second azimuth rail spaced apart for each other, a first altitude rail and a second altitude rail spaced apart for each other, an azimuth controller coupled to the first azimuth rail and the second azimuth rail that control the azimuth angle of a mount by moving the first azimuth rail and the second azimuth rail, a tilt controller coupled to the first altitude rail and the second altitude rail that control the tilt angle of the mount by moving the first altitude rail and the second altitude rail, and a controller that controls the azimuth controller and the tilt controller;
controlling the azimuth angle of the solar module using the azimuth controller and the first and second azimuth rails; and
controlling the tilt of the solar module using the tilt controller and the first and second altitude rails.

11. The method claim 10 further comprising automatically calibrating the azimuth controller and the tilt controller during start-up.

12. The method of claim 10 further comprising automatically determining a horizon during start-up.

13. A solar module installation, comprising:
at least one solar module mounted on a control module;
at least one solar module mounted on an extension module wherein the control module controls the movement of the solar module mounted in the control module and the extension module; and
the control module further comprising a first azimuth rail and a second azimuth rail spaced apart for each other; a first altitude rail and a second altitude rail spaced apart for each other; an azimuth controller coupled to the first azimuth rail and the second azimuth rail that control the azimuth angle of the solar module mounted on the control module by moving the first azimuth rail and the second azimuth rail; a tilt controller coupled to the first altitude rail and the second altitude rail that control the tilt angle of the solar module mounted on the control module by moving the first altitude rail and the second altitude rail; and a controller that controls the azimuth controller and the tilt controller.
